(19) United States
(12) Patent Application Publication
(10) Pub. No.: US 2025/0311289 A1
(43) Pub. Date: Oct. 2, 2025

(54) SEMICONDUCTOR DEVICE AND MANUFACTURING METHOD THEREFOR

(71) Applicants: Kabushiki Kaisha Toshiba, Tokyo (JP); Toshiba Electronic Devices & Storage Corporation, Tokyo (JP)

(72) Inventor: Hiroshi HASEGAWA, Nomi Ishikawa (JP)

(21) Appl. No.: 18/830,464

(22) Filed: Sep. 10, 2024

(30) Foreign Application Priority Data
Apr. 1, 2024 (JP) 2024-059116

(51) Int. Cl. H01L 29/78; H01L 29/45; H01L 29/47; H01L 29/49; H01L 29/66

(52) U.S. Cl. CPC H10D 30/668; H10D 30/0297; H10D 64/62; H10D 64/64; H10D 64/668

(57) ABSTRACT

A semiconductor device includes: a first electrode; a semiconductor layer provided on the first electrode; a second electrode provided on the semiconductor layer; a control electrode provided in the semiconductor layer via an insulating region; a first conductive portion facing the control electrode, electrically connected to the second electrode, and having a first work function; a first semiconductor region of a first conductivity type provided in the semiconductor layer, sandwiched between the insulating region and the first conductive portion, and forming a Schottky junction with the first conductive portion; a second semiconductor region of a first conductivity type provided in the semiconductor layer, located on the first semiconductor region, and having an impurity concentration higher than the first semiconductor region; and a second conductive portion electrically connected to the second electrode, having a second work function, and forming an ohmic junction with the second semiconductor region.

### CROSS-REFERENCE TO RELATED APPLICATIONS

This application is based upon and claims the benefit of priority from the prior Japanese Patent Application No. 2024-059116, filed on Apr. 1, 2024; the entire contents of which are incorporated herein by reference.

### FIELD

Embodiments described herein relate generally to a semiconductor device and a manufacturing method therefor.

### BACKGROUND

Semiconductor devices such as metal oxide semiconductor field effect transistors (MOFETs) that have switching functions are known. In such semiconductor devices, the on-resistance is preferably low.

### BRIEF DESCRIPTION OF THE DRAWINGS

FIG. 1 is a cross-sectional view illustrating a semiconductor device according to a first embodiment;

FIG. 2 is an enlarged view illustrating a region A in FIG. 1;

FIG. 3A is a cross-sectional view illustrating an example of a process of manufacturing the semiconductor device according to the first embodiment;

FIG. 3B is a cross-sectional view illustrating an example of the process of manufacturing the semiconductor device subsequently to FIG. 3A according to the first embodiment;

FIG. 3C is a cross-sectional view illustrating an example of the process of manufacturing the semiconductor device subsequently to FIG. 3B according to the first embodiment;

FIG. 3D is a cross-sectional view illustrating an example of the process of manufacturing the semiconductor device subsequently to FIG. 3C according to the first embodiment;

FIG. 3E is a cross-sectional view illustrating an example of the process of manufacturing the semiconductor device subsequently to FIG. 3D according to the first embodiment;

FIG. 3F is a cross-sectional view illustrating an example of the process of manufacturing the semiconductor device subsequently to FIG. 3E according to the first embodiment;

FIG. 4 is a cross-sectional view illustrating a semiconductor device according to a modification of the first embodiment;

FIG. 5 is a cross-sectional view illustrating a semiconductor device according to a second embodiment;

FIG. 6A is a cross-sectional view illustrating an example of a process of manufacturing the semiconductor device according to the second embodiment;

FIG. 6B is a cross-sectional view illustrating an example of the process of manufacturing the semiconductor device subsequently to FIG. 6A according to the second embodiment;

FIG. 6C is a cross-sectional view illustrating an example of the process of manufacturing the semiconductor device subsequently to FIG. 6B according to the second embodiment;

FIG. 7 is a cross-sectional view illustrating a semiconductor device according to a third embodiment;

FIG. 8 is a cross-sectional view illustrating an example of a process of manufacturing the semiconductor device according to the third embodiment; and

FIG. 9 is a cross-sectional view illustrating a semiconductor device according to a modification of the third embodiment.

### DETAILED DESCRIPTION

A semiconductor device includes: a first electrode; a semiconductor layer provided on the first electrode; a second electrode provided on the semiconductor layer; a control electrode provided in the semiconductor layer via an insulating region; a first conductive portion facing the control electrode in a second direction orthogonal to a first direction oriented from the first electrode to the second electrode, electrically connected to the second electrode, and having a first work function; a first semiconductor region of a first conductivity type provided in the semiconductor layer, sandwiched between the insulating region and the first conductive portion, and forming a Schottky junction with the first conductive portion; a second semiconductor region of a first conductivity type provided in the semiconductor layer, located on the first semiconductor region, and having an impurity concentration higher than the first semiconductor region; and a second conductive portion electrically connected to the second electrode, having a second work function different from the first work function, and forming an ohmic junction with the second semiconductor region.

Hereinafter, embodiments according to the present invention will be described with reference to the drawings. The embodiments do not limit the present invention. The drawings are schematic or conceptual, and ratios of each portion and the like are not necessarily the same as actual ratios. In the specification and the drawings, the same elements as those described above with respect to the previously described drawings are denoted by the same reference numerals, and the detailed description thereof will be omitted as appropriate.

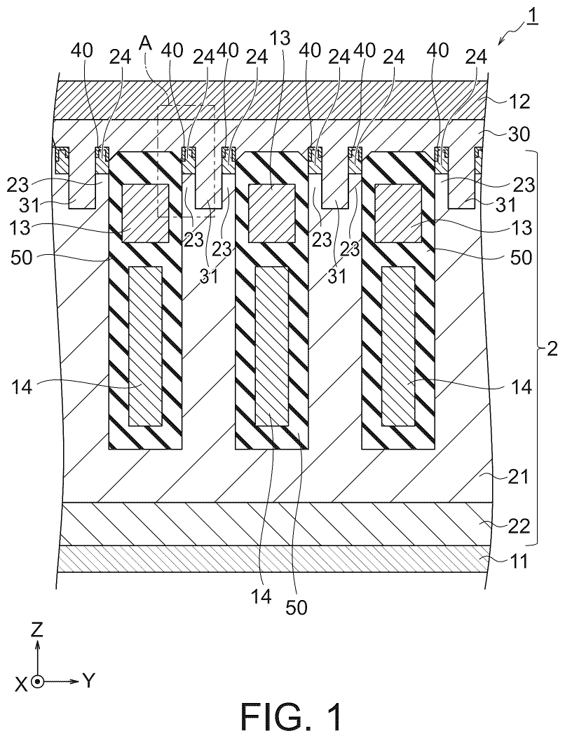

To facilitate description, an XYZ orthogonal coordinate system is adopted as illustrated in FIGS. 1 to 3. A Z-axis direction is a stacking direction (thickness direction) of semiconductor devices. In the Z-axis direction, the source electrode side is also referred to as “upper”, and the drain electrode side is also referred to as “lower”. However, this expression is used for convenience and independent of the direction of gravity. The Z-axis direction is a first direction in the claims. The Y-axis direction is a second direction in the claims. The X-axis direction is a third direction in the claims.

In the following description, notations of n⁺, n, n⁻, and p⁺, p, and p⁻ may be used to represent relative levels of impurity concentrations in conductivity types. That is, n⁺ indicates that an n-type impurity concentration is relatively higher than n, and n⁻ indicates that an n-type impurity concentration is relatively lower than n. p⁺ indicates that a p-type impurity concentration is relatively higher than p, and p⁻ indicates that a p-type impurity concentration is relatively lower than p. When both the p-type and n-type impurities are contained in each region, these notations represent a relative level of a net impurity concentration after the impurities have been compensated. The n-type, the n⁺ type, and the n type are examples of the first conductivity type in the claims. The p-type, the p⁺ type, and the p-type are examples of the second conductivity type in the claims. In the following description, the n-type and the p-type may be reversed. That is, the first conductivity type may be the p-type.

The impurity concentration of the semiconductor region can be measured by, for example, secondary ion mass spectrometry (SIMS). The relative level of the impurity concentration can also be determined from the level of a carrier concentration obtained by, for example, scanning capacitance microscopy (SCM).

A dimension such as a width of a contact portion can be measured by, through example, analysis of a surface and/or a cross section by a transmission electron microscope (TEM), an energy dispersive X-ray spectroscopy (EDX), or a scanning electron microscope (SEM).

The composition of the conductive portion or the like can be analyzed by energy dispersive X-ray spectroscopy or the like.

### First Embodiment

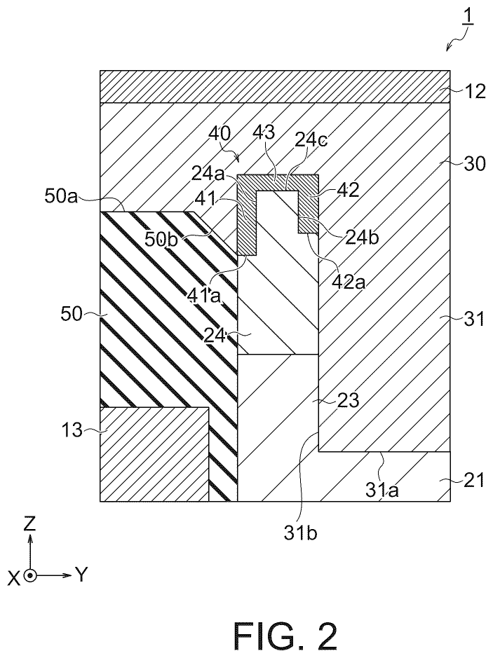

A semiconductor device 1 according to a first embodiment will be described with reference to FIGS. 1 and 2. FIG. 1 is a cross-sectional view illustrating the semiconductor device 1 according to the first embodiment. FIG. 2 is an enlarged view illustrating a region A in FIG. 1.

The semiconductor device 1 according to the present embodiment is a vertical transistor. More specifically, the semiconductor device 1 is a vertical MOSFET that switches between on and an off states by controlling a thickness of a Schottky barrier by controlling a potential of a gate electrode (a gate electrode 13 to be described below).

As illustrated in FIG. 1, the semiconductor device 1 includes a drain electrode (first electrode) 11, a semiconductor layer 2 provided on the drain electrode 11, and a source electrode (second electrode) 12 provided on the semiconductor layer 2.

The drain electrode 11 functions as a drain electrode of the semiconductor device 1. In the present embodiment, the drain electrode 11 is electrically connected to the drain region 22 provided in the semiconductor layer 2. The drain electrode 11 is formed of, for example, copper (Cu), titanium (Ti), tungsten (W), aluminum (Al), or the like.

Various semiconductor regions described to be below and the like are provided in the semiconductor layer 2. The semiconductor layer 2 may be an epitaxial layer, a semiconductor substrate, or a semiconductor substrate and an epitaxial layer disposed on the semiconductor substrate. In the present embodiment, the semiconductor layer 2 is silicon (Si). In this case, for example, arsenic (As), phosphorus (P), or antimony (Sb) is used as n-type impurities, and for example, boron (B) is used as p-type impurities. The semiconductor layer 2 may be formed of a compound semiconductor such as silicon carbide (SiC) or gallium nitride (GaN).

The source electrode 12 functions as a source electrode of the semiconductor device 1. In the present embodiment, the source electrode 12 is electrically connected to the conductive portion 30 (third conductive portion) and the conductive portion 31 which is a part of the conductive portion 30. The source electrode 12 is electrically connected to the conductive portion 30 via the conductive portion 40. The source electrode 12 is formed of, for example, copper (Cu), titanium (Ti), tungsten (W), aluminum (Al), or the like.

Although not illustrated, the source electrode 12 may include a plurality of metal layers formed of different materials. For example, the source electrode 12 may include a first metal layer formed of titanium (Ti) and/or titanium nitride (TiN) provided on the conductive portion 30, a second metal layer formed of tungsten (W) provided on the first metal layer, and a third metal layer formed of aluminum (Al) provided on the second metal layer.

Details of the semiconductor layer 2 will be described. As illustrated in FIG. 1, a drift region 21, a drain region 22, a thinned region (first semiconductor region) 23, a top region (second semiconductor region) 24, a gate electrode (control electrode) 13, an insulating region 50, and a conductive portion (first conductive portion) 31 are provided in the semiconductor layer 2. A conductive portion (second conductive portion) 40 is provided on the top region 24.

The drift region 21 functions as a drift region of the semiconductor device 1. The drift region 21 is disposed on the drain region 22 (above the drain electrode 11). The drift region 21 is, for example, an n type semiconductor region. The n-type impurity concentration of the drift region 21 is, for example, 1×10¹⁵ cm⁻³ or more and 2×10¹⁶ cm⁻³ or less.

The drain region 22 functions as a drain region of the semiconductor device 1. The drain region 22 is disposed between the drift region 21 and the drain electrode 11. The drain region 22 is, for example, an n⁺ type semiconductor region. The n-type impurity concentration of the drain region 22 is, for example, 1×10¹⁸ cm⁻³ or more and 1×10²¹ cm⁻³ or less.

The drain region 22 may not be provided. In this case, the drift region 21 is directly provided on the drain electrode 11, and the drain electrode 11 is electrically connected to the drift region 21. Alternatively, the drift region 21 may not be provided. In this case, for example, the drain region 22 is also provided at a position of the drift region 21.

The thinned region 23 is an n″ type semiconductor region that is located at the upper end portion of the drift region 21 in the semiconductor layer 2 and has the same impurity concentration as the drift region 21. The thinned region 23 is sandwiched between the insulating region 50 and the conductive portion 31 and extends in the X-axis direction. The thinned region 23 may have an impurity concentration different from that of the drift region 21.

The top region 24 is provided in the semiconductor layer 2 and is located on the thinned region 23. The top region 24 extends in the X-axis direction. The top region 24 has a higher impurity concentration than the thinned region 23. The top region 24 is, for example, an n⁺ type semiconductor region. The n-type impurity concentration of the top region 24 is, for example, 8×10¹⁹ cm⁻³ or more and 5×10²⁰ cm⁻³ or less.

In FIG. 2, the top region 24 is illustrated as a region different from the thinned region 23, but a boundary between the top region 24 and the thinned region 23 may be unclear because the impurity concentration continuously changes. However, a semiconductor region of a second semiconductor type, for example, a base region or the like, is not provided between the top region 24 and the thinned region 23.

The gate electrode 13 functions as a gate electrode of the semiconductor device 1. The gate electrode 13 is provided in the semiconductor layer 2 via the insulating region 50 and extends in the X-axis direction. The gate electrode 13 is formed of, for example, polysilicon containing p-type or n-type impurities. The insulating region 50 is an insulating film containing, for example, silicon oxide or silicon nitride.

The conductive portion 31 is provided to reach the drift region 21 from the upper surface of the semiconductor layer 2. More specifically, as illustrated in FIGS. 1 and 2, the conductive portion 31 is provided to partially face the gate electrode 13 in a direction (Y-axis direction) orthogonal to the thickness direction of the semiconductor layer 2. Here, the fact that a part of the conductive portion 31 faces the gate electrode 13 means that a lower end (tip) portion of the conductive portion 31 faces the gate electrode 13 in the Y-axis direction. As illustrated in FIG. 2, a direction from a boundary surface (Schottky junction surface) 31a between the conductive portion 31 and the drift region 21 to the gate electrode 13 is oriented in the Y-axis direction. The conductive portion 31 extends in the X-axis direction.

The conductive portion 31 is electrically connected to the source electrode 12. In the present embodiment, as illustrated in FIGS. 1 and 2, a conductive portion 30 formed of the same conductive material as the conductive portion 31 is provided between the upper surface of the semiconductor layer 2 and the source electrode 12, and the conductive portion 31 is electrically connected to the source electrode 12 via the conductive portion 30.

As illustrated in FIG. 2, the conductive portion 31 is provided to be in contact with the upper surface of the drift region 21 and the side surface of the thinned region 23. The conductive portion 31 includes a first conductive material that has a first work function, and forms a Schottky junction with the drift region 21 and the thinned region 23. When the first conductivity type is the n-type, the first conductive material is platinum (Pt), cobalt (Co), nickel (Ni), or the like. That is, when the first conductivity type is the n-type, the conductive portion 31 contains at least one of platinum, cobalt, and nickel. In the present embodiment, the conductive portion 31 is formed of platinum.

The Schottky junction between the conductive portion 31 and the drift region 21 forms a Schottky barrier near the boundary surface 31a between the conductive portion 31 and the drift region 21. The Schottky junction between the conductive portion 31 and the thinned region 23 forms a Schottky barrier near the boundary surface 31b between the conductive portion 31 and the thinned region 23. When these Schottky barriers are thick, a current does not substantially flow from the drain electrode 11 to the source electrode 12, and the semiconductor device 1 turns off. Conversely, when at least one of the Schottky barriers is thin, a current such as a tunnel current flows from the drain electrode 11 to the source electrode 12, and the semiconductor device 1 turns on. By controlling the potential of the gate electrode 13, the thickness of the Schottky barrier formed near the boundary surfaces 31a and 31b can be controlled to switch between the on and off states of the semiconductor device 1.

The conductive portion 40 is provided on the top region 24 and is electrically connected to the source electrode 12. In the present embodiment, the conductive portion 30 is provided between the conductive portion 40 and the source electrode 12, and the conductive portion 40 is electrically connected to the source electrode 12 via the conductive portion 30. The conductive portion 40 extends in the X-axis direction.

The conductive portion 40 includes a second conductive material that has the second work function different from the first work function, and forms an ohmic junction with the top region 24. When the first conductivity type is the n-type, the second work function is lower than the first work function. When the first conductivity type is the n-type, the second conductive material is titanium silicide (TiSi), titanium nitride (TiN), titanium (Ti), platinum silicide (PtSi), cobalt silicide (CoSi), nickel silicide (NiSi), tantalum (Ta), tantalum nitride (TaN), hafnium (Hf), or the like. That is, when the first conductivity type is the n-type, the conductive portion 40 contains at least one of titanium silicide, titanium nitride, titanium, platinum silicide, cobalt silicide, nickel silicide, tantalum, tantalum nitride, and hafnium. In the present embodiment, the conductive portion 40 is formed of titanium silicide. When the first conductivity type is the p-type, the second work function is higher than the first work function.

As illustrated in FIG. 1, the semiconductor device 1 may include a field plate electrode (FP electrode) 14 provided in the semiconductor layer 2 via an insulating region 50. In the present embodiment, the FP electrode 14 is provided below the gate electrode 13 and extends in the X-axis direction. The FP electrode 14 is formed of, for example, polysilicon containing p-type or n-type impurities. The FP electrode 14 is electrically insulated from semiconductor layer 2 by the insulating region 50 and is electrically connected to the source electrode 12. By providing the FP electrode 14, when the semiconductor device 1 is in the off state, a depletion layer extends from the FP electrode 14 to the drift region 21 around the FP electrode 14 by a voltage applied between the 11 drain electrode and the source electrode 12. This depletion layer is connected to the depletion layer of the nearby FP electrode 14, and a pressure voltage of the semiconductor device 1 is improved. The semiconductor device 1 may include a field plate provided in the semiconductor layer 2 via an insulating region (not illustrated) different from the insulating region 50. Further, the FP electrode 14 may be provided to extend in a direction other than the X-axis direction (for example, the Y-axis direction).

As described above, the semiconductor device 1 according to the first embodiment includes: the gate electrode 13 that is provided in the semiconductor layer 2 via the insulating region 50; the conductive portion 31 that faces the gate electrode 13 in the Y-axis direction, is electrically connected to the source electrode 12, and has a first work function; the thinned region 23 of the first conductivity type that is provided in the semiconductor layer 2, is sandwiched between the insulating region 50 and the conductive portion 31, and forms a Schottky junction with the conductive portion 31; the top region 24 of the first conductivity type that is provided in the semiconductor layer 2, is located on the thinned region 23, and has an impurity concentration higher than the thinned region 23; and the conductive portion 40 that is electrically connected to the source electrode 12, has the second work function different from the first work function, and forms the ohmic junction with the top region 24.

That is, in the present embodiment, in the semiconductor device 1 in which the thickness of the Schottky barrier is controlled to switch between the on and off states by controlling a potential of the gate electrode 13, the conductive portion 40 that forms an ohmic junction with the top region 24 is provided in addition to the conductive portion 31 that forms a Schottky junction with the drift region 21 and the thinned region 23. Accordingly, in the on state of the semiconductor device 1, a current between the drain and the source can flow through the ohmic junction that has contact resistance smaller than that of the Schottky junction. Therefore, the on resistance of the semiconductor device 1 can be reduced.

In the present embodiment, the top region 24 that forms an ohmic junction with the conductive portion 40 has a higher impurity concentration than the thinned region 23. Accordingly, the contact resistance between the conductive portion 40 and the top region 24 can be reduced, and the on-resistance of the semiconductor device 1 can be further reduced.

As illustrated in FIG. 2, the upper end of the top region 24 may protrude from an upper surface 50a of the insulating region 50, and the conductive portion 40 may be provided to wrap the upper end of the top region 24. More specifically, the conductive portion 40 may include a first portion 41 provided on the gate electrode 13 side of the top region 24, a second portion 42 provided on the conductive portion 31 side of the top region 24, and a third portion 43 provided on the upper side of the top region 24. In the example of FIG. 2, the first portion 41 of the conductive portion 40 is in contact with a first side surface 24a of the top region 24 on the gate electrode 13 side, the second portion 42 of the conductive portion 40 is in contact with a second side surface 24b of the top region 24 on the conductive portion 31 side, and the third portion 43 of the conductive portion 40 is in contact with an upper surface 24c of the top region 24 connecting the first side surface 24a and the second side surface 24b. Since the conductive portion 40 is provided to wrap the upper end of the top region 24 in this manner, an area of the ohmic junction formed between the conductive portion 40 and the top region 24 increases, and the on-resistance of the semiconductor device 1 can be further reduced.

As illustrated in FIG. 2, the insulating region 50 may have an upper surface 50a and an inclined surface 50b. The inclined surface 50b connects the upper surface 50a and the lower end 41a of the first portion 41 of the conductive portion 40. By providing the inclined surface 50b, the lower end 41a of the first portion 41 is positioned below the upper surface 50a of the insulating region 50. Therefore, the area of the ohmic junction formed between the conductive portion 40 and the top region 24 increases, and the on-resistance of the semiconductor device 1 can be further reduced. The lower end 41a of the first portion 41 of the conductive portion 40 may be positioned below the example of FIG. 2 as long as the lower end 41a is positioned above the upper end of the gate electrode 13. Accordingly, the on-resistance of the semiconductor device 1 can be further reduced.

The lower end 42a of the second portion 42 of the conductive portion 40 may be positioned below the example of FIG. 2 as long as the lower end 42a is positioned above the upper end of the gate electrode 13. Accordingly, the area of the ohmic junction formed between the conductive portion 40 and the top region 24 increases, and the on-resistance of the semiconductor device 1 can be further reduced.

### <Method of Manufacturing Semiconductor Device 1>

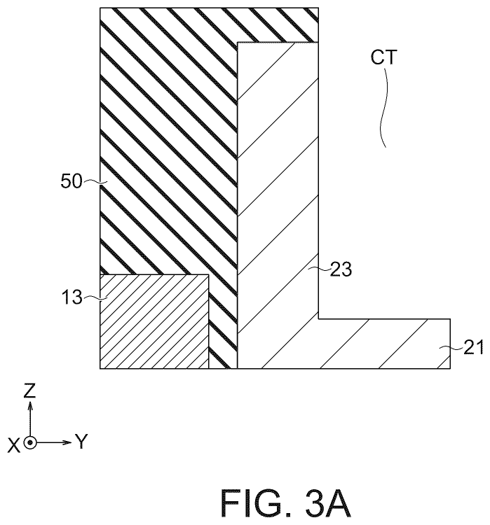

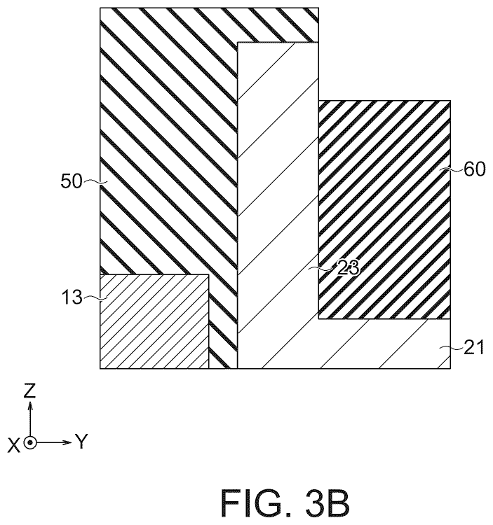

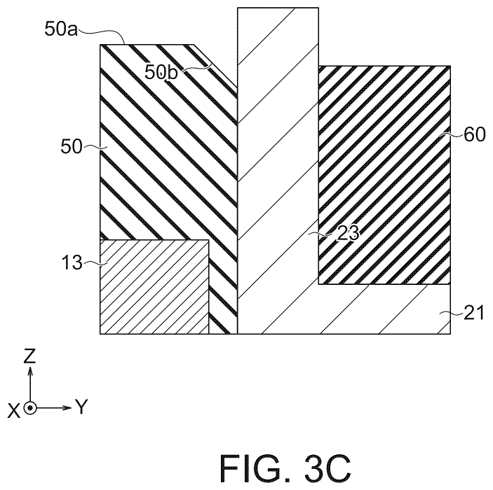

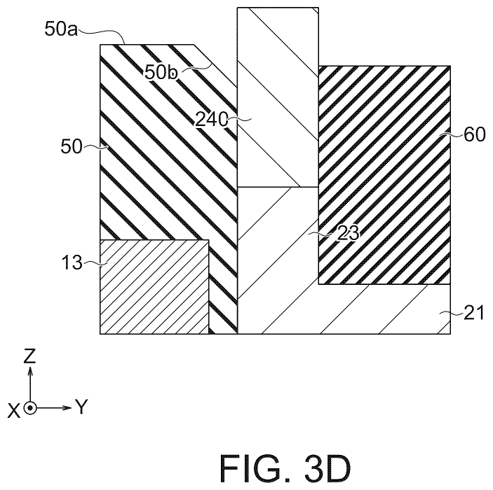

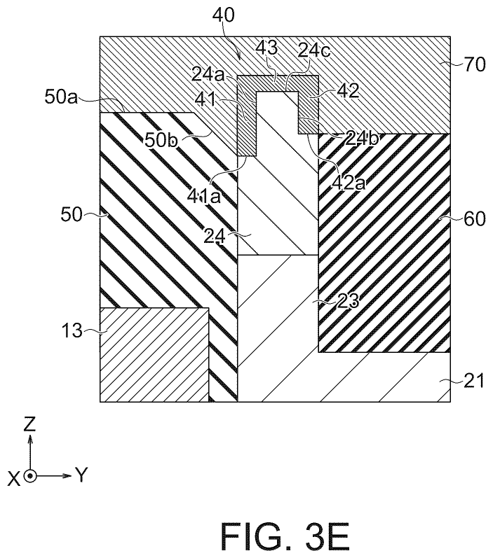

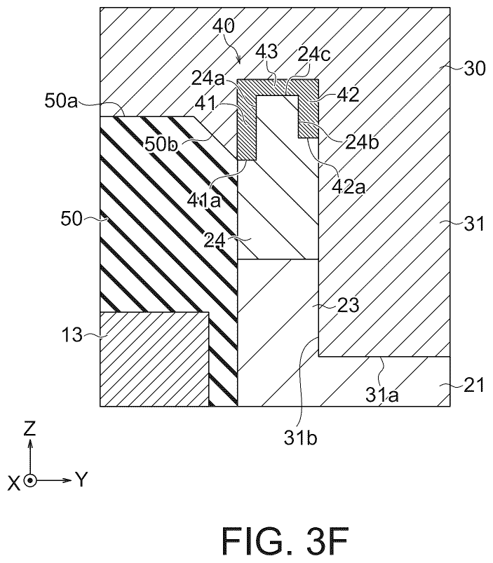

Next, an example of a method of manufacturing the semiconductor device 1 according to the present embodiment will be described with reference to FIGS. 3A to 3F. FIGS. 3A to 3F are cross-sectional views illustrating an example of a process of manufacturing the semiconductor device according to the first embodiment, and are enlarged views illustrating a portion corresponding to a region A in FIG. 1.

First, a semiconductor layer including a drift region (first semiconductor region) 21 and a gate electrode (control electrode) 13 provided in the drift region 21 via the insulating region 50 is prepared. Such a semiconductor layer is obtained, for example, as follows. First, a semiconductor substrate including the drift region 21 is prepared. Thereafter, a gate trench is formed on the upper surface of the semiconductor substrate by reactive ion etching (RIE) or the like. Thereafter, an insulating region is formed in the gate trench by thermal oxidation or the like. Thereafter, a part of the insulating region is removed by RIE or the like to form a trench in the insulating region. Thereafter, a conductive material such as polysilicon is deposited in the trench of the insulating region by chemical vapor deposition (CVD) or the like, and the excessive conductive material is etched back to form the gate electrode 13. Thereafter, an insulating material is deposited to embed the gate electrode 13 and cover the upper surface of the semiconductor substrate other than the gate trench. Thereafter, the upper surface of the insulating material is planarized by chemical mechanical polishing (CMP) or the like. Accordingly, the insulating region 50 is formed.

Next, as illustrated in FIG. 3A, a contact trench CT that faces the gate electrode 13 is formed in the drift region 21 by RIE or the like. The contact trench CT is formed with a space from the insulating region 50. Accordingly, a thinned region (second semiconductor region) 23 is formed in the drift region 21. The thinned region 23 is sandwiched between the insulating region 50 and the contact trench CT.

Next, as illustrated in FIG. 3B, a sacrificial film 60 for filling the contact trench CT is formed. The sacrificial film 60 is formed of an insulating material such as silicon nitride (SIN). The sacrificial film 60 is specifically formed as follows. First, the contact trench CT is filled by sputtering or the like, and an insulating material such as silicon nitride is deposited to cover the upper surface of the insulating region 50. Thereafter, the upper surface of the insulating material is planarized by CMP or the like. Thereafter, the upper portion of the insulating material is etched back by wet etching or the like to expose the insulating region 50. The height of the lower end 42a of the second portion 42 of the conductive portion (first conductive portion) 40 formed in a subsequent step can be changed by changing a height of the upper end of the sacrificial film 60 (see FIG. 3E).

Next, as illustrated in FIG. 3C, the upper portion of the insulating region 50 is removed by wet etching or the like to expose the upper surface of the thinned region 23. In the present embodiment, the insulating region 50 is further removed to form the inclined surface 50b connecting the upper surface 50a and the thinned region 23. Accordingly, in addition to the upper surface of the thinned region 23, the side surface of the thinned region 23 on the gate electrode 13 side is exposed. In this step, the upper surface of the thinned region 23 remains to be exposed, and the inclined surface 50b may not be formed.

Next, as illustrated in FIG. 3D, ion implantation of the impurities of the first conductivity type is performed on the top of the thinned region 23. When the first conductivity type is the n-type, the impurities are, for example, arsenic. Accordingly, a scheduled region 240 that will be the top region 24 by activation through the subsequent heat treatment is formed in the upper portion of the thinned region 23. By performing ion implantation, at least a part of the scheduled region 240 is amorphized, and silicidation can be promoted in a subsequent step. Since a portion of the upper surface of the semiconductor layer other than the thinned region 23 is covered with the insulating region 50 or the sacrificial film 60, the ion implantation in this step may be performed in a range wider than the width of the thinned region 23 on the upper surface of the semiconductor layer. Accordingly, the scheduled region 240 can be easily formed. The third semiconductor region according to the method of manufacturing a semiconductor device in the claims may be the scheduled region 240 described herein or may be the top region 24 after the activation through heat treatment.

Next, as illustrated in FIG. 3E, a metal layer 70 is formed to embed the scheduled region 240. The metal layer 70 is, for example, titanium. Thereafter, by performing heat treatment, ions implanted into the scheduled region 240 are activated, and the top region 24 of the first conductivity type is formed. At the same time, the scheduled region 240 is silicided near the boundary surface with the metal layer 70, and the conductive portion 40 is formed. The top region 24 is a semiconductor region of the first conductivity type that has a higher impurity concentration than the drift region 21 and the thinned region 23. The conductive portion 40 has the first work function and forms an ohmic junction with the top region 24. The conductive portion 40 is, for example, titanium silicide. The heat treatment may be performed before the metal layer 70 is formed and after the metal layer 70 is formed. That is, the step of forming the top region 24 by activation through heat treatment and the step of forming the conductive portion 40 by silicidation through heat treatment may be separately performed.

Next, as illustrated in FIG. 3F, the metal layer 70 is removed by wet etching or the like. Thereafter, the sacrificial film 60 is removed by wet etching or the like to expose the contact trench CT. Thereafter, the conductive portion (second conductive portion) 31 filling the contact trench CT is formed by sputtering or the like. The conductive portion 31 has the second work function different from the first work function, and forms a Schottky junction with the drift region 21 and the thinned region 23. Thereafter, the conductive portion 31 and the conductive portion 40 are covered with the conductive portion 30 by sputtering or the like. The conductive portion 30 may be formed continuously after the conductive portion 31 is formed.

Thereafter, although not illustrated, n-type impurities are ion-implanted into the lower surface of the semiconductor layer, and heat treatment is performed to form the drain region 22. Thereafter, the drain electrode 11 and the source electrode 12 are formed so that the semiconductor layer is sandwiched by the drain electrode 11 and the source electrode 12. That is, the drain electrode 11 is formed on the lower surface of the semiconductor layer, and the source electrode 12 is formed on the conductive portion 30.

Through the above steps, the semiconductor device 1 is manufactured.

According to the manufacturing method of the present embodiment, by forming the conductive portion 31 to fill the contact trench CT, the Schottky junction between the conductive portion 31 and the thinned region 23 can be formed even when the step coverage of the material of the conductive portion 31 is low.

### Modification of First Embodiment

### <Semiconductor Device 1A>

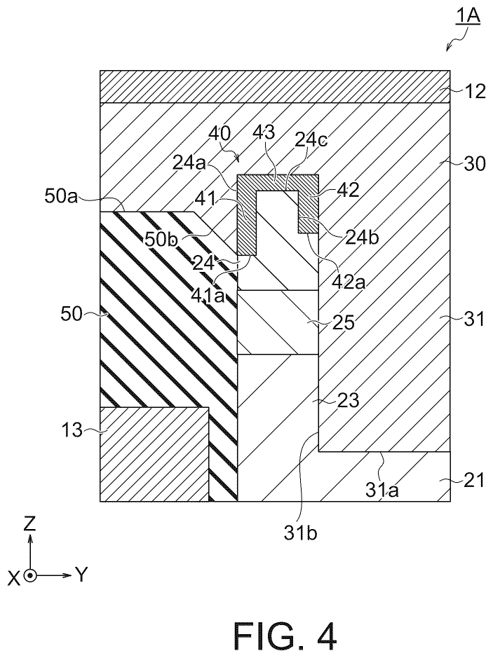

Next, a semiconductor device 1A according to a modification of the first embodiment will be described with reference to FIG. 4. FIG. 4 is a cross-sectional view illustrating the semiconductor device 1A according to the modification of the first embodiment, and is an enlarged view illustrating a portion corresponding to the region A in FIG. 1. One of differences between the present modification and the first embodiment is presence of a connection region 25. Hereinafter, the present modification will be described focusing on differences from the first embodiment.

As illustrated in FIG. 4, the semiconductor device 1A further includes the connection region 25 in addition to the configuration of the semiconductor device 1 according to the first embodiment. The connection region 25 is an n-type semiconductor region provided between the thinned region 23 and the top region 24. An impurity concentration of the connection region 25 is, for example, higher than the impurity concentration of the thinned region 23 and lower than the impurity concentration of the top region 24. The n-type impurity concentration of the connection region 25 is, for example, 3×10¹⁷ cm⁻³ or more and 2×10¹⁹ cm⁻³ or less. In FIG. 4, the top region 24 is illustrated as a region different from the connection region 25, but a boundary between the top region 24 and the connection region 25 may be unclear because the impurity concentration continuously changes. The same applies to the boundary between the connection region 25 and the thinned region 23.

The connection region 25 is formed by, for example, performing ion implantation of n-type impurities from the upper surface of the semiconductor substrate before the contact trench CT is formed and then performing heat treatment in the process of manufacturing the semiconductor device 1. The top region 24 is formed by performing ion implantation of n-type impurities on the top of the connection region 25 and then performing heat treatment in a process similar to that in FIG. 3D.

According to the present modification, by providing the connection region 25, the impurity concentration of the top region 24 can be further improved. Therefore, contact resistance between the conductive portion 40 and the top region 24 can be further reduced, and on-resistance of the semiconductor device 1A can be further reduced.

### Second Embodiment

### <Semiconductor Device 1B>

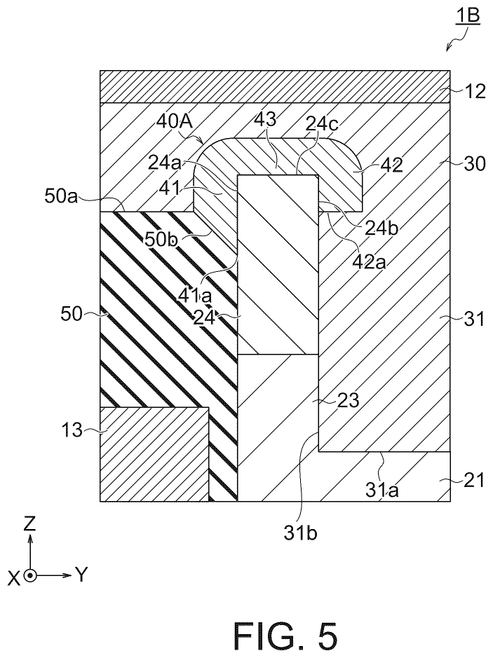

A semiconductor device 1B according to a second embodiment will be described with reference to FIG. 5. FIG. 5 is a cross-sectional view illustrating the semiconductor device 1B according to the second embodiment. The semiconductor device 1B according to the present embodiment includes a conductive portion 40A that has a width larger than that of the conductive portion 40 of the first embodiment. Hereinafter, the present embodiment will be described focusing on the differences from the first embodiment.

As illustrated in FIG. 5, the semiconductor device 1B includes the conductive portion 40A that has a width larger than that of the top region 24. That is, a length of the conductive portion 40A in the Y direction is longer than a length of the top region 24 in the Y direction. As illustrated in FIG. 5, the conductive portion 40A may have a wider width than the thinned region 23. The conductive portion 40A is provided instead of the conductive portion 40 of the semiconductor device 1 according to the first embodiment. In the present embodiment, the conductive portion 40A is provided to fill a groove portion defined by the inclined surface 50b and the first side surface 24a of the top region 24.

According to the present embodiment, the resistance of the conductive portion 40A can be reduced by providing the conductive portion 40A that has a width wider than the top region 24. Therefore, the on-resistance of the semiconductor device 1B can be further reduced.

### <Method of Manufacturing Semiconductor Device 1B>

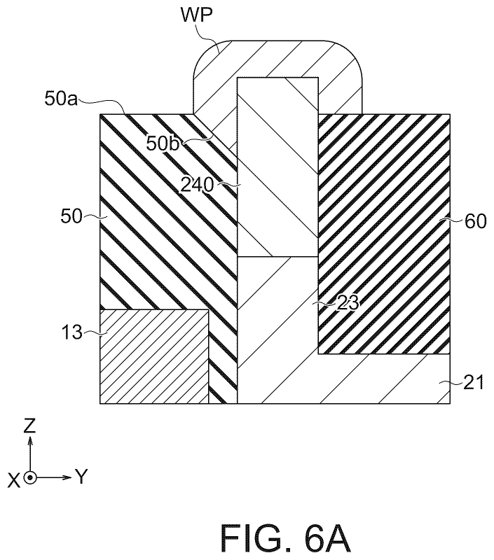

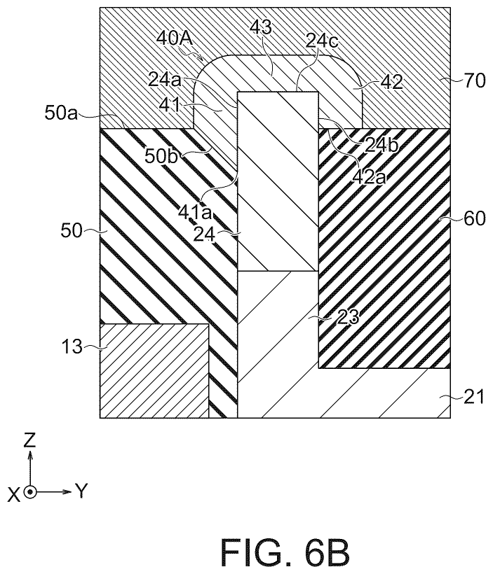

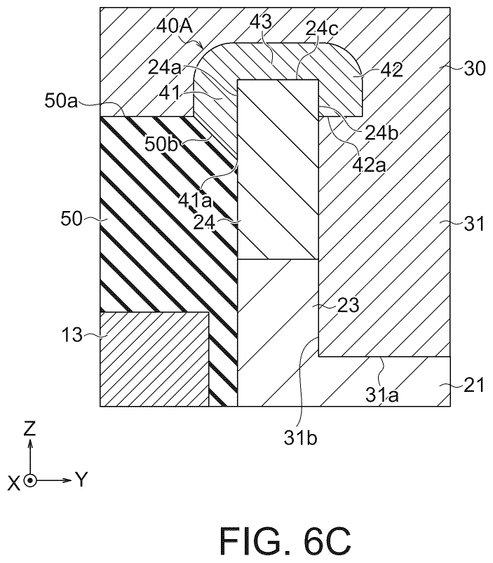

A method of manufacturing the semiconductor device 1B according to the second embodiment will be described with reference to FIGS. 6A to 6C. FIGS. 6A to 6C are cross-sectional views illustrating an example of a process of manufacturing the semiconductor device according to the second embodiment, and are enlarged views illustrating a portion corresponding to a region A in FIG. 1.

First, of the processes of manufacturing the semiconductor device 1 according to the above-described first embodiment, the processes until the process of forming the scheduled region 240 described with reference to FIG. 3D are performed. In the present embodiment, the scheduled region 240 may be formed so that the scheduled region 240 is shallower than the scheduled region 240 according to the first embodiment, that is, the lower end of the scheduled region 240 in FIG. 3D is located at a higher position in consideration of diffusion of impurities contained in the scheduled region 240 due to heating in a step of performing subsequent epitaxial growth. The shallow scheduled region 240 can be formed by, for example, pulse plasma lateral aligned doping (PLAD) using a plasma doping device.

Next, as illustrated in FIG. 6A, a wide region WP wider than the scheduled region 240 is formed on the scheduled region 240 by selective epitaxial growth or the like. For example, the width of the scheduled region 240 is 50 nm, and the width of the wide region WP is 200 nm.

Next, as illustrated in FIG. 6B, the metal layer 70 is formed on the wide region WP. Thereafter, by performing heat treatment, the ions implanted in the scheduled region 240 are activated, and the top region 24 is formed. At the same time, the wide region WP is silicided, and the conductive portion (first conductive portion) 40A is formed. The conductive portion 40A has the first work function and forms an ohmic junction with the top region 24.

Next, as illustrated in FIG. 6C, the excess metal layer 70 is removed by wet etching or the like. Thereafter, the sacrificial film 60 is removed by wet etching or the like to expose the contact trench CT. Thereafter, the conductive portion (second conductive portion) 31 filling the contact trench CT is formed by sputtering or the like. Thereafter, the conductive portion 31 and the conductive portion 40 are covered with the conductive portion 30 by sputtering or the like. The conductive portion 30 may be formed continuously after the conductive portion 31 is formed.

The subsequent steps are the same as those in the first embodiment.

Through the above steps, the semiconductor device 1B is manufactured.

According to the manufacturing method of the present embodiment, by forming the wide region WP, it is possible to prevent the concentration of silicon from relatively decreasing in the conductive portion 40A and prevent the resistance of the conductive portion 40A from becoming high. Therefore, an increase in the on-resistance of the semiconductor device 1A can be suppressed.

When the wide region WP is formed by selective epitaxial growth, a dopant gas that has impurities of the first conductivity type may be supplied. Accordingly, it is possible to inhibit a decrease in the impurity concentration of the top region 24 due to diffusion of impurities accompanying heating during epitaxial growth. Therefore, an increase in the on-resistance of the semiconductor device 1A can be further suppressed.

After the wide region WP is formed, ion implantation of impurities of the first conductivity type may be further performed in the wide region WP. Accordingly, at least a part of the wide region WP is amorphized, and silicidation of the wide region WP can be promoted.

### Third Embodiment

### <Semiconductor Device 1C>

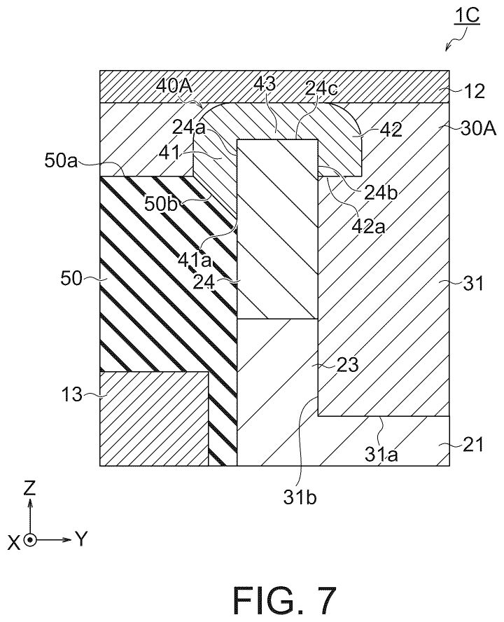

A semiconductor device 1C according to a third embodiment will be described with reference to FIG. 7. FIG. 7 is a cross-sectional view illustrating the semiconductor device 1C according to the third embodiment, and is an enlarged view illustrating a portion corresponding to a region A in FIG. 1. One of differences between the present embodiment and the second embodiment is a mode of electrical connection between the source electrode 12 and the conductive portion 40A. Hereinafter, the present embodiment will be described focusing on the differences from the second embodiment.

As illustrated in FIG. 7, the conductive portion (second conductive portion) 40A of the semiconductor device 1C is in direct contact with the source electrode (second electrode) 12. That is, the conductive portion 40A is in contact with the source electrode 12 without involving the conductive portion (third conductive portion) 30A.

According to the present embodiment, the conductive portion 30 that has the first work function can be prevented from affecting the electrical connection between the source electrode 12 and the conductive portion 40A that has the second work function.

### <Method of Manufacturing Semiconductor Device 1C>

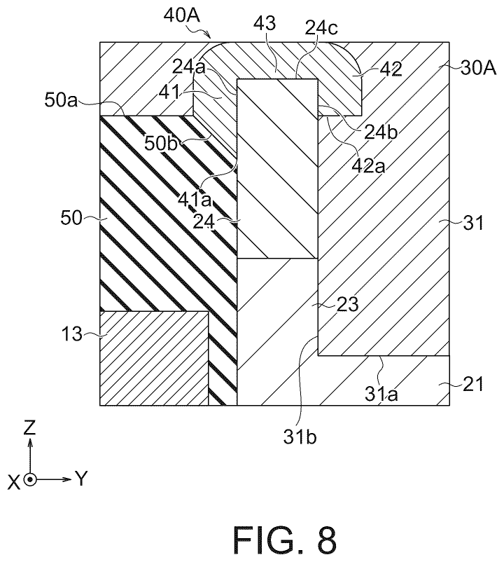

A method of manufacturing the semiconductor device 1C according to the third embodiment will be described with reference to FIG. 8. FIG. 8 is a cross-sectional view illustrating an example of a process of manufacturing the semiconductor device 1C according to the third embodiment, and is an enlarged view illustrating a portion corresponding to the region A in FIG. 1.

First, of the processes of manufacturing the semiconductor device 1B according to the second embodiment described above, the processes until the process of forming the conductive portion (second conductive portion) 31 and the conductive portion (second conductive portion) 30 are performed.

Next, as illustrated in FIG. 8, the upper portion of the conductive portion 30 is removed by etching or the like to expose the upper surface of the conductive portion (first conductive portion) 40A. Accordingly, the conductive portion 30A thinner than the conductive portion 30 is formed.

The subsequent steps are the same as those in the second embodiment. However, when the source electrode 12 is formed, the source electrode 12 is formed to cover the upper surface of the conductive portion 40A. Accordingly, the source electrode 12 in direct contact with the conductive portion 40A is formed.

Through the above steps, the semiconductor device 1C is manufactured.

### Modification of Third Embodiment

### <Semiconductor Device 1D>

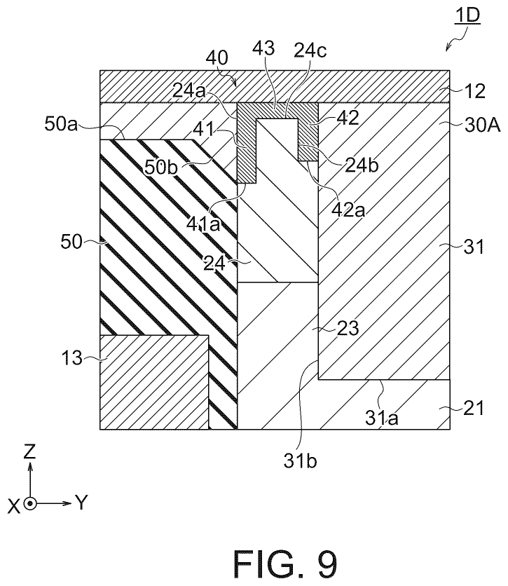

A semiconductor device 1D according to a modification of the third embodiment will be described with reference to FIG. 9. FIG. 9 is a cross-sectional view illustrating the semiconductor device 1D according to the modification of the third embodiment, and is an enlarged view illustrating a portion corresponding to the region A in FIG. 1. In the above-described third embodiment, the conductive portion 40A in the second embodiment is in direct contact with the source electrode 12. Conversely, in a modification of the third embodiment, the conductive portion 40 in the first embodiment is in direct contact with the source electrode 12.

As illustrated in FIG. 9, the conductive portion (second conductive portion) 40 of the semiconductor device 1D is in direct contact with the source electrode 12 without involving the conductive portion (third conductive portion) 30.

Accordingly, the degree of freedom in designing the semiconductor device 1D can be improved.

The semiconductor device 1D can be manufactured, for example, as follows. First, of the processes of manufacturing the semiconductor device 1 according to the first embodiment, a process of forming the conductive portion (second conductive portion) 31 and the conductive portion (second conductive portion) 30 is performed. Thereafter, the upper portion of the conductive portion 30 is removed by etching or the like to expose the upper surface of the conductive portion (first conductive portion) 40. Accordingly, the conductive portion 30A is formed. The subsequent steps are the same as those in the third embodiment.

In each of the above embodiments and modifications, the gate electrode 13, the conductive portion (first conductive portion) 31, the thinned region (first semiconductor region) 23, the top region (second semiconductor region) 24, and the conductive portions (second conductive portions) 40 and 40A all extend in the X-axis direction. That is, each of the embodiments and the modifications has been described as an example applied to a case of a stripe shape in which trenches such as a gate trench and a contact trench are arranged in parallel. The present invention is not limited thereto, and the embodiments and the modifications can also be applied to a case of a dot-shaped trench and a case of a mesh-shaped trench in which trenches intersect when viewed from the upper surface of the semiconductor layer 2 in the thickness direction.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a first electrode;
a semiconductor layer provided on the first electrode;
a second electrode provided on the semiconductor layer;
a control electrode provided in the semiconductor layer via an insulating region;
a first conductive portion facing the control electrode in a second direction orthogonal to a first direction oriented from the first electrode to the second electrode, electrically connected to the second electrode, and having a first work function;
a first semiconductor region of a first conductivity type provided in the semiconductor layer, sandwiched between the insulating region and the first conductive portion, and forming a Schottky junction with the first conductive portion;
a second semiconductor region of a first conductivity type provided in the semiconductor layer, located on the first semiconductor region, and having an impurity concentration higher than the first semiconductor region; and
a second conductive portion electrically connected to the second electrode, having a second work function different from the first work function, and forming an ohmic junction with the second semiconductor region.

2. The semiconductor device according to claim 1, wherein the second conductive portion has a wider width than the second semiconductor region.

3. The semiconductor device according to claim 2, wherein the second conductive portion is in direct contact with the second electrode.

4. The semiconductor device according to claim 2, wherein a third conductive portion formed of a same conductive material as the first conductive portion is provided between the second conductive portion and the second electrode.

5. The semiconductor device according to claim 1, wherein the second conductive portion is in direct contact with the second electrode.

6. The semiconductor device according to claim 1, wherein a third conductive portion formed of a same conductive material as the first conductive portion is provided between the second conductive portion and the second electrode.

7. The semiconductor device according to claim 1, wherein
the second conductive portion includes
a first portion provided on the control electrode side of the second semiconductor region,
a second portion provided on the first conductive portion side of the second semiconductor region, and
a third portion provided on an upper side of the second semiconductor region.

8. The semiconductor device according to claim 7, wherein the insulating region has an upper surface and an inclined surface, wherein
the inclined surface connects the upper surface and a lower end of the first portion of the second conductive portion.

9. The semiconductor device according to claim 8, wherein lower ends of the first portion and the second portion of the second conductive portion are located closer to the second electrode than an upper end of the control electrode.

10. The semiconductor device according to claim 7, wherein lower ends of the first portion and the second portion of the second conductive portion are located closer to the second electrode than an upper end of the control electrode.

11. The semiconductor device according to claim 1, wherein the first conductive portion is in contact with a side surface of the first semiconductor region.

12. The semiconductor device according to claim 1, wherein the first conductivity type is an n-type, and the first work function is higher than the second work function.

13. The semiconductor device according to claim 12, wherein
the first conductive portion contains at least one of platinum, cobalt, and nickel, and
the second conductive portion contains at least one of titanium silicide, titanium nitride, titanium, platinum silicide, cobalt silicide, nickel silicide, tantalum, tantalum nitride, or hafnium.

14. The semiconductor device according to claim 13, wherein the first conductive portion contains platinum, and the second conductive portion contains titanium silicide.

15. The semiconductor device according to claim 1, wherein the control electrode, the first conductive portion, the first semiconductor region, the second semiconductor region, and the second conductive portion all extend in a third direction orthogonal to the first and second directions.

16. A method of manufacturing a semiconductor device, the method comprising:
preparing a semiconductor layer including a first semiconductor region of a first conductivity type and a control electrode provided in the first semiconductor region via an insulating region;
forming a trench, in the first semiconductor region, facing the control electrode;
forming a sacrificial film filling the trench;
forming a third semiconductor region of the first conductivity type provided on a second semiconductor region and having an impurity concentration higher than the first semiconductor region by performing ion implantation of impurities of the first conductivity type in the second semiconductor region, wherein the second semiconductor region is sandwiched between the insulating region and the trench in the first semiconductor region;
forming a first conductive portion having a first work function and forming an ohmic junction with the third semiconductor region;
exposing the trench by removing the sacrificial film;
forming a second conductive portion that fills the trench, has a second work function different from the first work function, and forms a Schottky junction with the second semiconductor region; and
forming first and second electrodes to sandwich the semiconductor layer.

17. The method of manufacturing the semiconductor device according to claim 16, wherein the first conductive portion is formed by, after the third semiconductor region is formed, forming a metal layer on the third semiconductor region, and performing heat treatment.

18. The method of manufacturing the semiconductor device according to claim 16, wherein
a wide region wider than the third semiconductor region is formed by epitaxially growing an upper portion of the third semiconductor region after the third semiconductor region is formed and before the first conductive portion is formed, and
the first conductive portion is formed by forming a metal layer on the wide region and performing heat treatment.

19. The method of manufacturing the semiconductor device according to claim 16, wherein
a part of the second conductive portion is removed to expose the first conductive portion after the second conductive portion is formed and before the second electrode is formed, and
the second electrode is formed to cover the exposed first conductive portion.

20. The method of manufacturing the semiconductor device according to claim 16, wherein after the sacrificial film is formed and before the third semiconductor region is formed, an upper portion of the insulating region is removed to expose the control electrode side of the second semiconductor region.
